(19) United States
(12) Patent Application Publication
(10) Pub. No.: US 2009/0161417 A1
(43) Pub. Date: Jun. 25, 2009

(54) Two cell per bit phase change memory

(76) Inventors: Richard Fackenthal, Carmichael, CA (US); Ruili Zhang, Rancho Cordova, CA (US)

Correspondence Address: TROP, PRUNER & HU, P.C., 1616 S. VOSS RD., SUITE 750, HOUSTON, TX, 77057-2631, US

(21) Appl. No.: 12/004,535

(22) Filed: Dec. 21, 2007

(51) Int. Cl. G11C 11/00

(52) U.S. Cl. 365/163

(57) ABSTRACT

A phase change memory array may have a plurality of cells in which a bit is determined by a single cell. In addition, a portion of the array may include a plurality of cells which are combined so that two cells form one bit of memory. One of the combined cells is programmed to the complementary state of the other of the combined cells. Thus, the bit is determined by reading the indicator bit which is correctly programmed and comparing it to the complement cell. As a result, the bit may be very reliable because the read window is twice as wide as that used in a conventional phase change memory which compares the selected bit current to a reference current that is midway between the programmed and unprogrammed states.

### BACKGROUND

This relates generally to phase change memories.

Phase change memory devices use phase change materials, i.e., materials that may be electrically switched between a generally amorphous and a generally crystalline state, for electronic memory application. One type of memory element utilizes a phase change material that may be, in one application, electrically switched between a structural state of generally amorphous and generally crystalline local order or between different detectable states of local order across the entire spectrum between completely amorphous and completely crystalline states. The state of the phase change material is also non-volatile in that, when set in either a crystalline, semi-crystalline, amorphous, or semi-amorphous state representing a resistance value, that value is retained until changed by another programming event, as that value represents a phase or physical state of the material (e.g., crystalline or amorphous). The state is unaffected by removing electrical power.

### BRIEF DESCRIPTION OF THE DRAWINGS

FIG. 1 is an enlarged, cross-sectional view of a memory element in accordance with one embodiment of the present invention;

FIG. 2 is a circuit schematic for the structure shown in FIG. 1 in accordance with one embodiment;

FIG. 3 is the plane architecture for one embodiment of the present invention;

FIG. 4 is a tile architecture for one embodiment of the present invention; and

FIG. 5 is a system depiction for one embodiment of the present invention.

### DETAILED DESCRIPTION

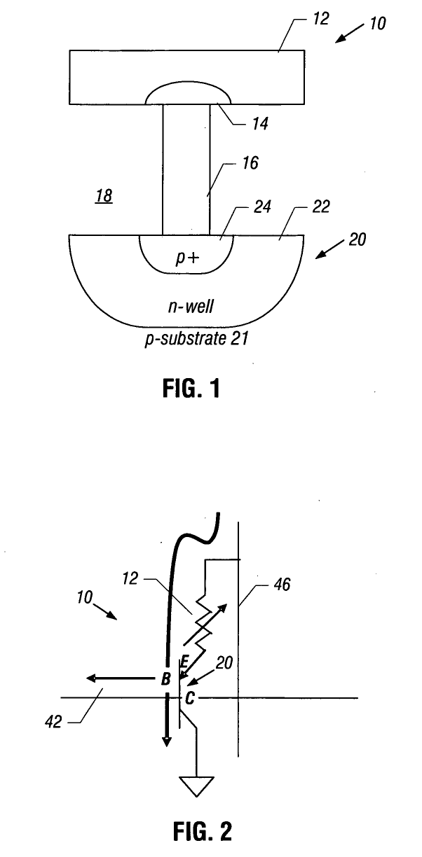

Referring to FIG. 1, a phase change memory cell 10 includes a memory element 10 and a bipolar junction transistor access device or select switch 20. The select switch 20 includes a p-type substrate 21, an n-well 22, a p+ well 24, within the n-well 22. In the illustrated embodiment, the select switch 20 is a PNP bipolar transistor, but NPN bipolar transistors would also be used.

The memory element 10 includes a chalcogenide layer 12 and a heater 16 in one embodiment. The heater 16 may be formed of a material, such as titanium silicon nitride, within a pore within a dielectric 18 in accordance with one embodiment. The heater 16 may be coupled to a phase changing chalcogenide layer 12. The region 14 of the layer 12 that actually changes phase is proximate to the heater 16 which heats the layer 12 to cause transitions between amorphous and crystalline phases.

Referring to FIG. 2, the PNP bipolar junction transistor select switch 20 includes a base B, an emitter E, and a collector C. It is coupled to the memory element 10, conceptualized as a variable resistor. The resistance varies based on the phase of the phase changing region 14. Namely, when the region 14 is more amorphous, the resistance is higher than when the region 14 is more crystalline.

Each cell 10 is connected to a word line 42 and a bitline 46. Thus, the bitline current runs through the word line 42 via the base B of the bipolar junction transistor select switch 20. The emitter current runs to ground through the bitline 46.

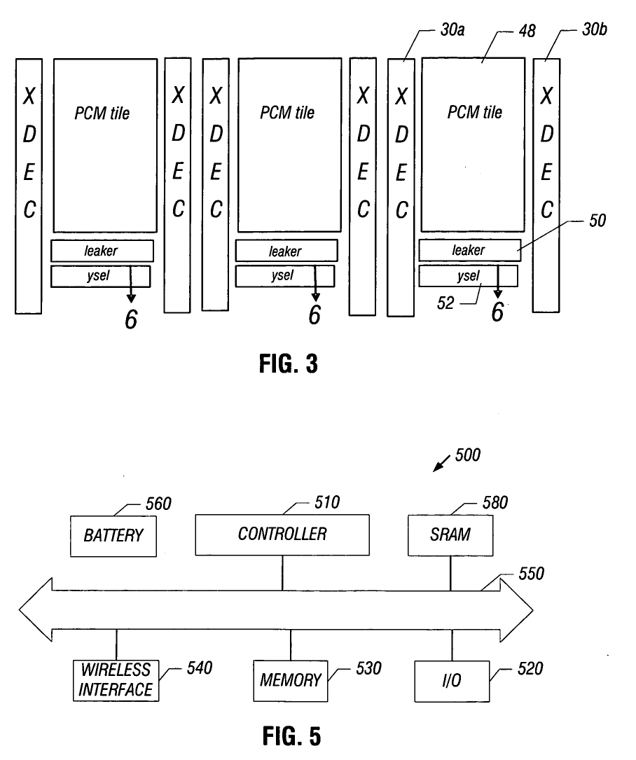

A memory array may be made up of one or more tiles. The tiles may consist of a number of actual memory cells, together with some dummy or redundant rows and columns. A plurality of tiles make up a plane, as shown in FIG. 3. Thus, the plane may include a plurality of tiles 48 and, in this example, three tiles 48, each addressed by a pair of X decoders 30a and 30b and a Y select 52. The Y select 52 is through a leaker 50.

The leakers are directly connected to ground. The Y select decoder may be a two to four decoder and may be used for decoding with both leaker select and Y selects. Once the Y selects turn on, the leakers shut off. Once the Y selects turn off, the leakers turn on.

In some embodiments, some bits of memory are based on two cells. The two cells that make up the bit are oppositely programmed. One cell, called the indicator cell, stores the state of the bit and the other, called the complement cell, stores its complement. Thus, one cell may be amorphous, when the other cell is crystalline and vice versa. In some embodiments, the two cells that make up a bit may be placed adjacent to each other for the purpose of better bitline and Y path matching.

Sensing is done by accessing the two cells that make up a bit at the same time. The current drawn by each of the cells may be compared, in one embodiment, to determine whether the bit is programmed or unprogrammed. By using two cells to form the bit, larger read margin may be obtained that would be the case with a reference current.

Typically, a cell is sensed by comparison to a reference current whose current midway between the current of the programmed and unprogrammed state. Thus, the margin in the conventional or typical technology is the difference between the reference current and the indicated state. But this is half the margin or read window that exists between the programmed and unprogrammed cells that make up a bit in accordance with some embodiments of the present invention.

Thus, the reliability of the memory may be very high and, as a result, it may be utilized to store code whose accuracy is very important. One example of such code is microcode. A microcode storage unit may be used to help mature a technology by allowing engineering versions of microcode to be run for analysis purposes. Ideally, since the microcode is used for memory development, it is desired that the microcode module be more robust than its underlying technology. In accordance with some embodiments of the present invention, the microcode may be stored with two cells per bit, while the ultimate product and the conventional memory array of that product may use one cell per bit.

Thus, in some embodiments, the overall memory array 43 may include a region 56 for microcode which is two cells per bit and a region of conventional memory array which is one cell per bit. Because of the increased margin available through the two cell per bit memory, reliability may be significantly higher than with the one cell per bit memory array.

To program a bit in the two cell per bit memory, the indicator cell is programmed to its appropriate state and then the complement cell is programmed in the complementary state. To read the bit, the indicator cell's current is compared to the complement cell's current. If the indicator cell draws more current, then the bit is set and if the indicator cell draws less current, the bit is reset.

Thus, in some embodiments of the present invention, the two cell per bit memory does not use any reference current for sensing.

As an example of the applicability of some embodiments of the present invention, the main array may use one cell per bit, but may have a problem where many cells are difficult to set. The read current might not be so high and the set distribution may be low, encroaching on the reference current. If, on the other hand, a small module with two cells per bit has this same problem, the weakly set indicator cell is still well above the reset complement cell, and, thus, there is a more robust bit of data.

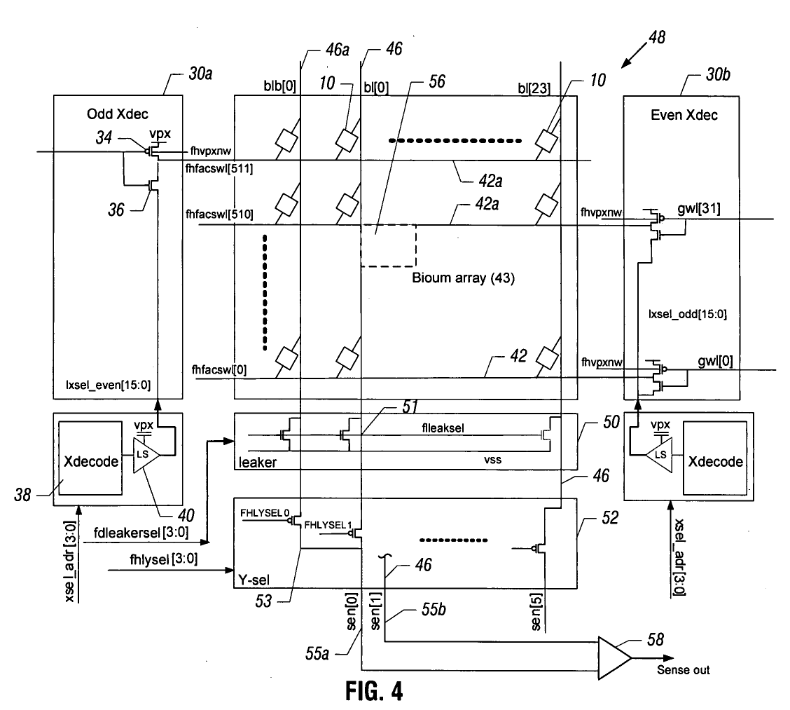

Referring to FIG. 4, the architecture of a tile 48 includes an array 43 of cells 10. The array includes word lines 42 and bitlines 46. It may also include redundant bitlines 46a. An even X decoder 30b may be provided on one side of the array 43 and an odd X decoder 30a may be provided on the other side. A plurality of cells may make up the main array 43 and may also be used in the redundant array. Leakers 50 may be provided with the Y select 52. The Y select 52 includes Y select transistors 53 and a sense output and a sense output complement 55a and 55b. Thus, the state of one of the cells that make up the bit is output on the sense output 55a and the state of the other cell that makes up the complementary pair is output on the output 55b.

In one embodiment, the array 43 has 24 bitlines 46. The memory 48 also includes a pair of redundant bitlines 46a and a set of redundant word lines 42a. The X decoders 30a and 30b include an X decode unit 38 coupled to an amplifier 40. The leaker 50 includes a plurality of leaker transistors 51, coupled to leaker select lines to select the appropriate leaker for the selected column.

Programming of the phase change material to alter the state or phase of the material may be accomplished by applying voltage potentials to the word line 42 and bitline 46, thereby generating a voltage potential across any select device and memory element including a phase change material. When the voltage potential is greater than the threshold voltages of the select switch 20 and memory element, then an electrical current may flow through the element in response to the applied voltage potentials, and may result in heating of the phase change material.

This heating may alter the memory state or phase or at least a portion thereof. Altering the phase or state may alter the electrical characteristic of memory material, e.g., the resistance of the material may be altered by altering the phase of the memory material. Memory material may also be referred to as a programmable resistive material.

In the “reset” state, memory material may be in an amorphous or semi-amorphous state and in the “set” state, memory material may be in an a crystalline or semi-crystalline state. The resistance of memory material in the amorphous or semi-amorphous state may be greater than the resistance of memory material in the crystalline or semi-crystalline state. It is to be appreciated that the association of reset and set with amorphous and crystalline states, respectively, is a convention and that at least an opposite convention may be adopted.

Using electrical current, memory material may be heated to a relatively higher temperature to amorphosize memory material and “reset” memory material (e.g., program memory material to a logic “0” value). Heating the volume of memory material to a relatively lower crystallization temperature may crystallize memory material and “set” memory material (e.g., program memory material to a logic “1” value). Various resistances of memory material may be achieved to store information by varying the amount of current flow and duration through the volume of memory material.

Turning to FIG. 5, a portion of a system 500 in accordance with an embodiment of the present invention is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, a cellular network, although the scope of the present invention is not limited in this respect.

System 500 may include a controller 510, an input/output (I/O) device 520 (e.g. a keypad, display), static random access memory (SRAM) 560, a memory 530, and a wireless interface 540 coupled to each other via a bus 550. A battery 580 may be used in some embodiments. It should be noted that the scope of the present invention is not limited to embodiments having any or all of these components.

Controller 510 may comprise, for example, one or more microprocessors, digital signal processors, microcontrollers, or the like. Memory 530 may be used to store messages transmitted to or by system 500. Memory 530 may also optionally be used to store instructions that are executed by controller 510 during the operation of system 500, and may be used to store user data. Memory 530 may be provided by one or more different types of memory. For example, memory 530 may comprise any type of random access memory, a volatile memory, a non-volatile memory such as a flash memory and/or a memory such as memory discussed herein.

I/O device 520 may be used by a user to generate a message. System 500 may use wireless interface 540 to transmit and receive messages to and from a wireless communication network with a radio frequency (RF) signal. Examples of wireless interface 540 may include an antenna or a wireless transceiver, although the scope of the present invention is not limited in this respect.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
sensing the state of a phase change memory cell by comparing a characteristic of the cell to the same characteristic of a complementarily programmed cell.

2. The method of claim 1 comprising:
providing a phase change memory array including a plurality of cells; and
at least some of the said cells being paired to form a bit made up of two cells per bit.

3. The method of claim 1 including programming a bit by programming one cell to a selected state and a complement cell to the opposite state.

4. The method of claim 3 including reading the bit by accessing both the one cell and the complement cell at the same time and comparing the current drawn by the two cells.

5. The method of claim 1 including forming a phase change memory which includes a first array portion that includes one cell per bit and a second array portion with two cells per bit.

6. The method of claim 1 including forming an array with two cells per bit that does not use a reference current for sensing the two cells per bit.

7. The method of claim 2 including comparing the current drawn by one of the cells to the current drawn by the other of the cells that make up the bit.

8. The method of claim 7 including programming one of the cells to the opposite phase of the other of said cells.

9. The method of claim 1 including using two bits per cell to store a microcode.

10. The method of claim 1 including forming a memory made up of bits in which the read margin of the bits is equal to the difference between the current drawn by a programmed and an unprogrammed cell.

11. A phase change memory comprising:
an array of phase change memory cells; and
a sense amplifier to sense the state of a phase change memory cell by comparing a characteristic of the cell to the same characteristic of a complementarily programmed cell.

12. The memory of claim 11 where some of the cells of said array are paired to form a bit made up of two cells per bit.

13. The memory of claim 12 where one cell of a bit is programmed to the state to be sensed and a complement cell is programmed to the opposite state.

14. The memory of claim 13 wherein both the one cell and the complement cell are accessed at the same time and the current drawn by the cells compared to sense the state of the one cell.

15. The memory of claim 11 wherein said memory include a first array portion with bits formed from one cell per bit and a second array portion with bits formed of two cells per bit.

16. The memory of claim 11, said sense amplifier to sense the state of the phase change memory cell without using a reference current.

17. The memory of claim 12, said sense amplifier to compare the current drawn by one of the cells to the current drawn by the other of the cells that make up a bit.

18. The memory of claim 17 wherein the cells are programmed to opposite phases.

19. The memory of claim 11 wherein said memory includes a microcode storage module.

20. The memory of claim 11 having a read margin equal to the difference between the current drawn by a programmed and an unprogrammed cell.

21. A system comprising:
a processor; and
a phase change memory coupled to said processor, said phase change memory including an array of phase change memory cells and a sense amplifier to sense the state of a phase change memory cell by comparing a characteristic of the cell to the same characteristic of a complementarily programmed cell.

22. The system of claim 21 wherein said memory include a first array portion with bits formed from one cell per bit and a second array portion with bits formed of two cells per bit.

23. The system of claim 21, said sense amplifier to sense the state of the phase change memory cell without using a reference current.

24. The system of claim 21 where some of the cells of said array are paired to form a bit made up of two cells per bit.

25. The system of claim 24, said sense amplifier to compare the current drawn by one of the cells to the current drawn by the other of the cells that make up a bit.
